(19) United States
(12) Patent Application Publication
(10) Pub. No.: US 2015/0017433 A1
(43) Pub. Date: Jan. 15, 2015

(54) COMPOSITE PLASMONIC NANOSTRUCTURE FOR ENHANCED EXTINCTION OF ELECTROMAGNETIC WAVES

(71) Applicants: Hossein ALISAFAEE, Charlotte, NC (US); Michael Anthony Fiddy, Huntersville, NC (US)

(72) Inventors: Hossein ALISAFAEE, Charlotte, NC (US); Michael Anthony Fiddy, Huntersville, NC (US)

(73) Assignee: The University Of North Carolina At Charlotte, Charlotte, NC (US)

(21) Appl. No.: 14/322,407

(22) Filed: Jul. 2, 2014

Related U.S. Application Data
(60) Provisional application No. 61/843,123, filed on Jul. 5, 2013.

(51) Int. Cl. H01L 31/0272; H01L 31/18; H01L 31/0352

(52) U.S. Cl. CPC H01L 31/02725; H01L 31/035218; H01L 31/18
USPC 428/338; 438/63; 252/512; 252/514

(57) ABSTRACT

The present disclosure explores and fabricates coupled plasmonic nanoparticles of gold (Au), silver (Ag), or aluminum (Al) onto nanorods or nanowires of zinc telluride (ZnTe), silicon (Si), germanium (Ge), or other semiconductor materials. Full-wave simulation is performed to obtain an optimum design for maximum light absorption. The nanorods, after being coated with a shell to form a p-n junction, or being imparted with a radial junction, are of interest for enhanced light harvesting in solar cells, for example. The fabrication method of such arrays is described. Modeling of the spectral properties using equivalent circuit theory is implemented to predict fabrication results and provide an intuitive approach regarding the design of these optical metamaterials with predetermined properties.

### CROSS-REFERENCE TO RELATED APPLICATION

The present patent application/patent claims the benefit of priority of co-pending U.S. Provisional Patent Application No. 61/843,123, filed on Jul. 5, 2013, and entitled “COMPOSITE PLASMONIC NANOSTRUCTURE FOR ENHANCED EXTINCTION OF ELECTROMAGNETIC WAVES,” the contents of which are incorporated in full by reference herein.

### STATEMENT OF FEDERALLY SPONSORED RESEARCH OR DEVELOPMENT

The U.S. Government may have certain rights in the present disclosure pursuant to Contract No. 1068050 awarded by the National Science Foundation (NSF).

### FIELD OF THE DISCLOSURE

The present disclosure relates generally to semiconductor materials used in optoelectronic devices. More specifically, the present invention relates to a composite plasmonic nanostructure for the enhanced extinction of electromagnetic waves.

### BACKGROUND OF THE DISCLOSURE

New semiconductor materials for use in optoelectronic devices—such as photovoltaics, light-emitting diodes, broad frequency field sensors, waveguides, gain media, and the like—are constantly being sought. Preferably, these devices take advantage of nanoscale effects.

Thus, the present disclosure explores and fabricates plasmonic nanoparticles of gold (Au) coupled to zinc telluride (ZnTe), silicon (Si), germanium (Ge), or other semiconductor(s) in the form of nanorod or nanowire structures, or even tandem nanowire structures. Silver (Ag) or aluminum (Al) could also be used for the plasmonic nanoparticles. Full-wave simulation is performed to obtain an optimum design for maximum light absorption. Nanowires or nanorods of ZnTe or other semiconductors, after forming a radial junction, are of interest for enhanced light harvesting in solar cells, for example. The fabrication method of such arrays is described. Modeling of the spectral properties using equivalent circuit theory is implemented to predict fabrication results and provide an intuitive approach regarding the design of these optical metamaterials with predetermined properties.

### BRIEF SUMMARY OF THE DISCLOSURE

In one exemplary embodiment, the present disclosure provides a composite plasmonic nanostructure for the enhanced extinction of electromagnetic waves, comprising: one or more elongate nanostructures of zinc telluride (ZnTe), silicon (Si), germanium (Ge), or other semiconductor material(s); and a gold (Au) nanoparticle disposed adjacent to the elongate semiconductor nanostructure(s). Silver (Ag) or aluminum (Al) could also be used for the nanoparticle. The Au nanoparticle is disposed adjacent to a free end of the elongate semiconductor nanostructure(s). Optionally, a zinc oxide (ZnO), or other suitable material, shell disposed around the elongate semiconductor nanostructure(s) or a radial junction is formed. The elongate semiconductor nanostructure has a length of between 200 nm and 10,000 nm and a diameter of between 10 nm and 2,000 nm. The Au nanoparticle has a diameter of between 10 nm and 2,000 nm. The Au nanoparticle and the elongate semiconductor nanostructure collectively provide the extinction of light having a wavelength of between 200 nm and 2,000 nm. The nanostructure further comprising a plurality of additional elongate semiconductor nanostructures and additional Au nanoparticles disposed adjacent to the elongate semiconductor nanostructure and Au nanopartical in an array, such as a vertical array. The elongate semiconductor nanostructure is grown using a vapor-liquid-solid (VLS) technique and the Au nanoparticle as a catalyst. Optionally, the elongate semiconductor nanostructure and the Au nanoparticle are disposed in a photovoltaic device.

In another exemplary embodiment, the present disclosure provides a method for providing a composite plasmonic nanostructure for the enhanced extinction of electromagnetic waves, comprising: providing one or more elongate nanostructures of zinc telluride (ZnTe), silicon (Si), germanium (Ge), or other semiconductor material(s); and providing a gold (Au) nanoparticle disposed adjacent to the elongate semiconductor nanostructure(s). Silver (Ag) or aluminum (Al) could also be used for the nanoparticle. The Au nanoparticle is disposed adjacent to a free end of the elongate semiconductor nanostructure(s). Optionally, the method further comprising providing a zinc oxide (ZnO), or other suitable material, shell disposed around the elongate semiconductor nanostructure(s) or a radial junction is formed. The elongate semiconductor nanostructure has a length of between 200 nm and 10,000 nm and a diameter of between 10 nm and 2,000 nm. The Au nanoparticle has a diameter of between 10 nm and 2,000 nm. The Au nanoparticle and the elongate semiconductor nanostructure collectively provide the extinction of light having a wavelength of between 200 nm and 2,000 nm. The nanostructure further comprising a plurality of additional elongate semiconductor nanostructures and additional Au nanoparticles disposed adjacent to the elongate semiconductor nanostructure and Au nanopartical in an array, such as a vertical array. The elongate semiconductor nanostructure is grown using a vapor-liquid-solid (VLS) technique and the Au nanoparticle as a catalyst. Optionally, the elongate semiconductor nanostructure and the Au nanoparticle are disposed in a photovoltaic device.

### BRIEF DESCRIPTION OF THE DRAWINGS

The present disclosure is illustrated and described herein with reference to the various drawings, in which like reference numbers are used to denote like components, as appropriate, and in which:

FIG. 1 is a schematic diagram illustrating one exemplary embodiment of the composite plasmonic nanostructure of the present disclosure and a plot illustrating the extinction spectra of incident light as a function of spacing between nanorod structures (Au nanosphere diameter is 100 nm, ZnTe nanowire diameter and length are 60 nm and 500 nm, respectively);

FIG. 2 is a graphic illustrating the power dissipation in the plasmonic nanorod structure of the present disclosure as a function of light wavelengths of (a) 1,000 nm, (b) 750 nm, (c) 650 nm, and (d) 600 nm (Au nanosphere diameter is 100 nm, ZnTe nanowire diameter and length are 60 nm and 500 nm, respectively, neighboring nanorods are placed with a spacing of 60 nm);

FIG. 3 is a plot illustrating the total extinction spectra as a function of nanorod length with a constant 60-nm spacing between structures;

FIG. 4 is a plot illustrating the power dissipation versus ZnTe nanostructure length at wavelengths of 600 and 650 nm (insets: absorption distribution of Au—ZnTe structure at 600 nm (right) and 650 nm (left));

FIG. 5 is (a) a schematic of the Au—ZnTe structure with equivalent circuit model elements where the electric field is applied perpendicular to the nanorod axis, (b) a circuit model of the unit cell including the array elements, and (c) an equivalent circuit of the whole structure including the periodicity condition;

FIG. 6 is a comparison of equivalent circuit response and simulation data points for the 60-nm separated array of FIG. 1; and

FIG. 7 is a schematic diagram illustrating exemplary embodiments of the composite plasmonic nanostructure of the present disclosure, highlighting their geometrical shapes and the inclusion of a rod-like semiconductor structure and a plasmonic or non-plasmonic nano-antenna adjacent to it.

### DETAILED DESCRIPTION OF THE DISCLOSURE

ZnTe is an interesting II-VI semiconductor material used in optoelectronic devices, such as photovoltaics, light-emitting diodes, broad frequency field sensors, waveguides, gain media, and the like. Some of these devices take advantage of nanoscale effects. ZnTe has been widely used because it is relatively easy to p-dope as compared to other II-VI materials. Two wide bandgap materials, such as a ZnTe/ZnO core-shell structure, configured as a type II heterojunction can be used to achieve an ideal effective bandgap for solar cells, thereby exploiting both optical coupling between the two components and unique electrical properties. Moreover, a vertical array of core-shell nanorods improves light trapping and potentially reduces charge diffusion lengths, further increasing photovoltaic efficiency. A main advantage of the core-shell structure for photovoltaic applications is to improve the charge separation and carrier transport. To grow such ZnTe nanorods, gold nanoparticles or islands can be used to catalyze nanowire growth via the vapor-liquid-solid (VLS) mechanism. Although, in photovoltaic devices, the gold catalyst may increase carrier recombination.

Noble metals, such as Au and silver (Ag), or transparent conductive oxides, e.g. indium tin oxide (ITO) and aluminum-doped zinc oxide (AZO), are known to exhibit plasmon oscillations when illuminated by light. During these oscillations, confined conduction electrons can be driven by the electric field of light into a resonant condition that is dependent on size, shape, material, and host medium. In the case of spherical nanoparticles of size a and permittivity ε in a host medium with permittivity εₕ, light scattering and absorption cross sections are defined by:

$${C}_{sca} = \frac{8 π}{3} {k}^{4} {a}^{6} {\vert \frac{ɛ - {ɛ}_{h}}{ɛ + 2 {ɛ}_{h}} \vert}^{2} , \\ {C}_{abs} = 4 π {ka}^{2} Im [ \frac{ɛ - {ɛ}_{h}}{ɛ + 2 {ɛ}_{h}} ] ,$$

where k is the wavenumber of light. At the plasmon resonance condition (ε=−2εₕ), scattering and absorption maxima occur, assuming that the imaginary parts of the permittivities are small. In the case of small particles with loss terms in their permittivities, absorption dominates over scattering. In the quasi-static regime, when the wavelength of light is much larger than the size of the nanoparticles, a dipole approximation may also be applied to study the interactions.

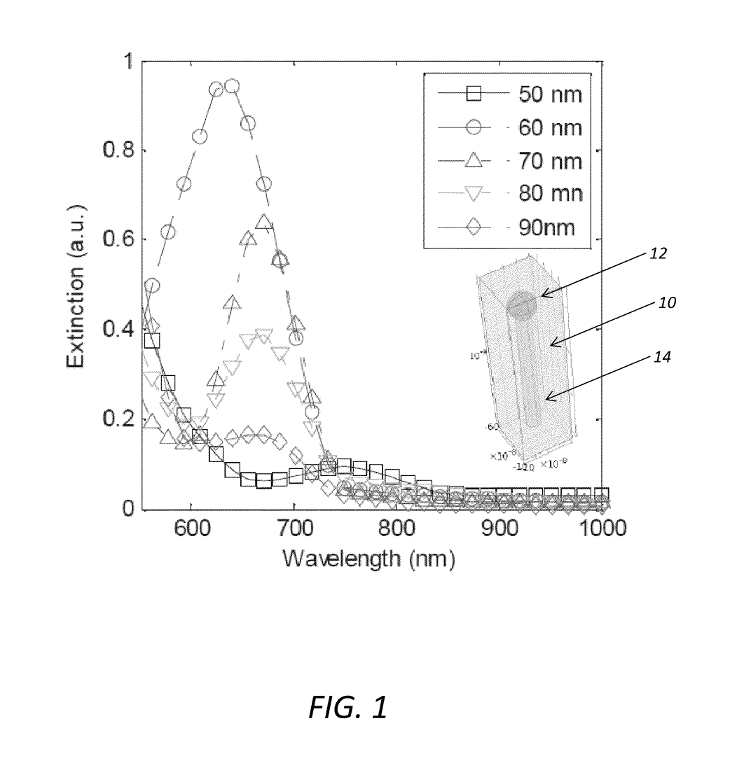

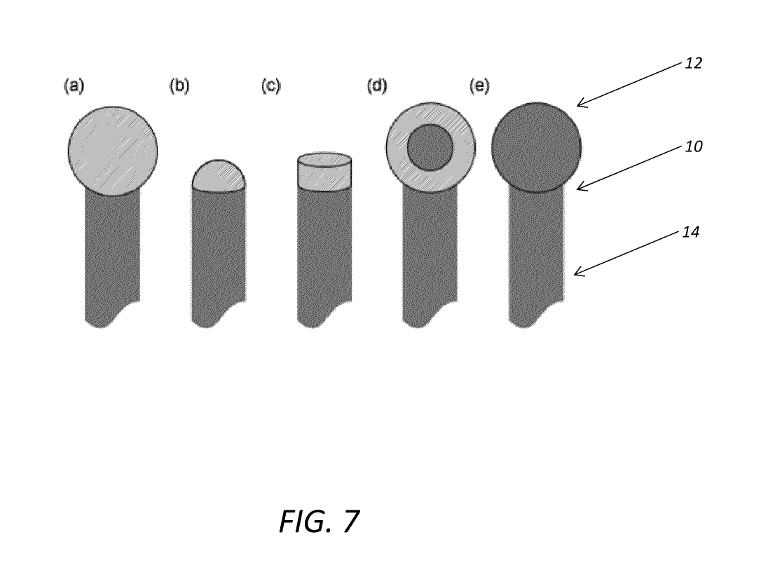

Referring specifically to FIG. 1, the plasmonic structures 10 of the present disclosure are ideally vertical arrays of Au nanospheres 12 and ZnTe nanorods 14, where the Au nanosphere catalyzes the ZnTe nanorod growth. (See also FIG. 7). This combination can be modeled as a metamaterial comprised of distinct nanocircuit elements. Each nanostructure can be represented as a nanoresistor, nanocapacitor, or nanoinductor. The coupling of these circuit elements represented by each Au nanosphere and ZnTe nanorod can then be described using circuit theory. We use an equivalent circuit method to predict the optical response of clusters of these nanostructures, and this provides a model that allows one to design the bulk electromagnetic properties of a metamaterial made from these units.

We numerically investigate the spectral response of plasmonic Au—ZnTe nanostructures to find the effects of structure parameters on light extinction and conversion efficiency. We use the Finite Element Method (FEM) to explore the best design for such a nanostructure array. Finally, we applied the circuit model to obtain intuition for the design of metamaterials. We use chemical vapor deposition (CVD) to fabricate the plasmonic Au—ZnTe nanostructures on silicon (Si) and then utilize scanning electron microscopy (SEM) and reflectance spectroscopy for characterization.

Using a FEM modeling software, we designed a unit cell of a coupled plasmonic Au—ZnTe structure 10, where an Au nanosphere 10 sits upon a ZnTe nanorod 12 (see FIG. 1). The unit cell includes an Au nanosphere of size 100 nm and a ZnTe nanowire of diameter and length 60 nm and 500 nm, respectively. The numbers are selected to match available fabrication capabilities. The incident light is linearly polarized and is incident from above the unit cell. Parallel to the axis of nanorod shown in FIG. 1, and in both directions, we employed Floquet boundary conditions to account for neighboring nanorod structures that can contribute to coupling effects in the computation process.

We investigate the spectral properties of this design upon change of different parameters to find a suitable set of final parameters in order to specify the fabrication and spectral response experiments. We have two main parameters which are: (1) the spacing between the adjacent plasmonic nanorods and (2) the length of ZnTe rods. Both parameters can be controlled in fabrication. The extinction spectra for a variety of reasonable spacings are calculated and shown in FIG. 1. It can be seen that the optical response of the structure is fairly sensitive to the spatial distribution of unit cells, and there is an enhanced extinction at a spacing of 60 nm. Since the extinction is defined as the sum of absorption and scattering, one can expect an enhanced absorption or scattering or even both. Enhanced scattering can result in the overall conversion efficiency of the structure since it helps to increase light-matter interaction, which eventually leads to an increase in the absorption. Also, absorption is the main effect we are looking for, since one of the major applications of the present disclosure is solar harvesting. Therefore, the more absorption, the better the efficiency.

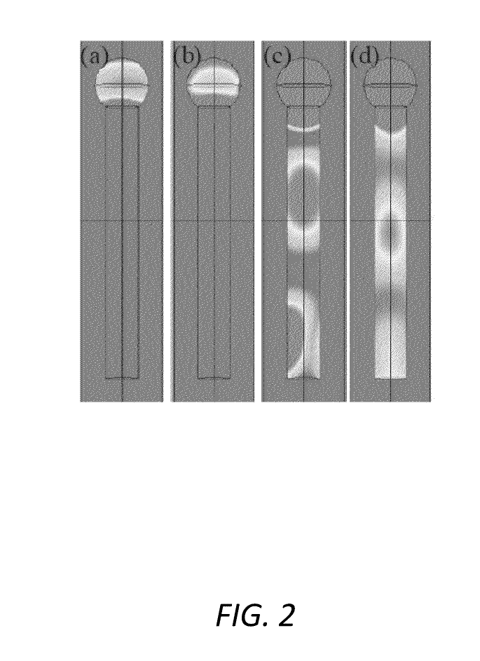

FIG. 2 demonstrates the power dissipation of light in the nanorod structures. Here, the spacing is 60 nm and length is 500 nm. The different spectral response of light absorption in the Au nanosphere and the ZnTe nanorod is observable. One can find the high absorption localization spots in the ZnTe rods (FIGS. 2(c) and 2(d)). There is also a high absorption region in the ZnTe near the boundary with the Au nanosphere. This can arise from a resonant forward scattering of the Au due to localized surface plasmon resonance (LSPR) effects, which help the absorption mechanism, directly. Therefore, it is now clear that the Au nanospheres can be utilized in a twofold application procedure for this structure; one is to help the growth of ZnTe nanorods, and another is to provide more absorption through LSPR.

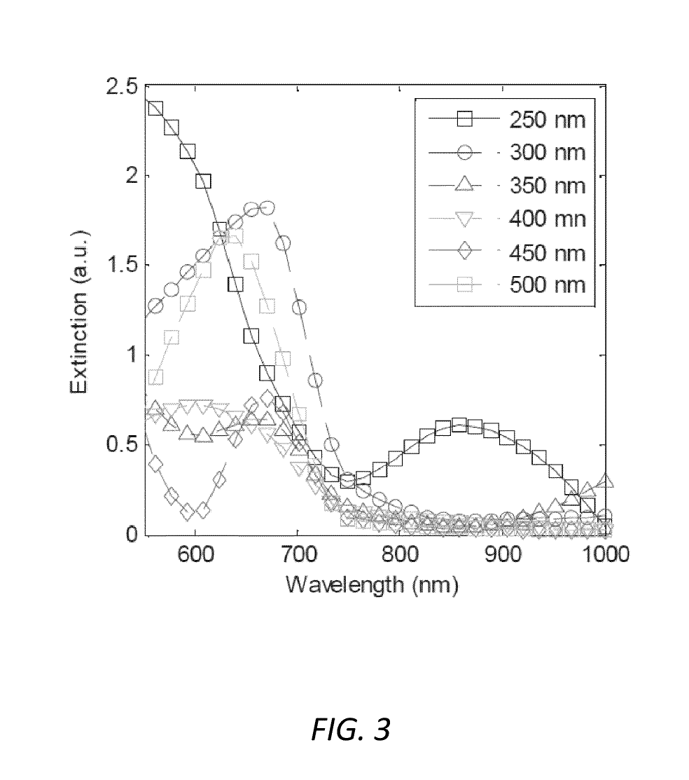

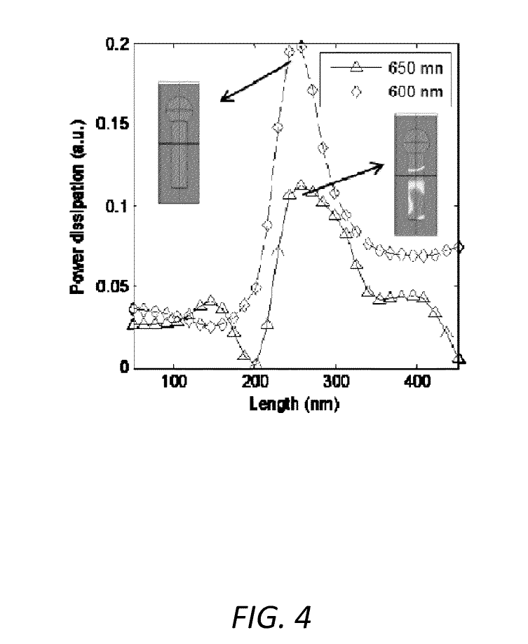

For consideration of the effects of nanorod length on the spectral response of our plasmonic structure, another study has been done with the length of ZnTe as the parameter. A reasonable minimum for the length of the nanorods is 250 nm. Therefore, the computation scans over this range with a suitable step which we have found to be 50 nm. The resulting spectra combined with the previous results for a length of 500 nm are represented in FIG. 3. The extinction coefficient is calculated in arbitrary units, and, again, it shows a spectral sensitivity based on the length parameter. Here, the extinction values are normalized to the volume of the unit cell. It can be seen that some of the length values resulted in a two or three fold enhancement in the extinction of light. However, as mentioned before, our application requires us to have high absorption in the semiconducting layer. For this reason, we need to separate the effect of the Au and look into the absorption of light happening only at the ZnTe nanorod. By intuition, one can see that the main spectral features occur at wavelengths around 600 nm and 650 nm. Therefore, we only study these two wavelengths for the latter effect. The results are shown in FIG. 4.

After separating the effects of Au and ZnTe, as is shown in FIG. 4, it is apparent that a huge increase in the amount of absorption occurs when the nanorod length is around 250 nm. Also, this absorption is significantly dependent on the wavelength of the light, which can lead to a two-fold increase from 600 nm to 650 nm. In the inset of FIG. 4, we can observe that the entire nanorod is acting as an absorber for light at 650 nm. However, at 600 nm, the absorption is not as efficient through the rod length.

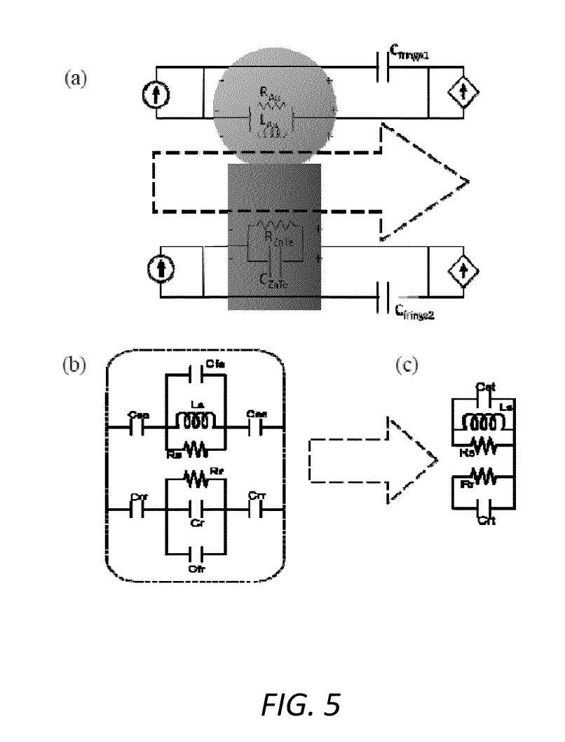

At the wavelength range of interest, the real part of the Au and ZnTe permittivity values are negative and positive, respectively. It has been suggested that they can be modeled as lumped circuit elements having a response similar to inductance and capacitance, respectively. Therefore, we can use an equivalent circuit to model not only the response of a single nanostructure, but also we can account for its periodicity. FIG. 5 shows the equivalent circuit model for an Au nanosphere and a ZnTe nanorod. The sphere is modeled by an inductor and also a resistor which demonstrate the losses. The ZnTe nanorod is modeled by a resistor and a capacitance. Both circuits have an independent current source which represents the displacement current, and also a voltage controlled current source is included denoting the coupling between the rod and plasmonic sphere.

Arrays of nanostructures can also be modeled by considering the periodicity condition. We assume a square lattice of such structures interacting with a linearly polarized light which is incident parallel to sides of the unit cell. We then need to add capacitors to account for the spacing between the spheres and rods (respectively, Cₛₛ and Cᵣᵣ in FIG. 5(b)). Since the spacing between the spheres is on the order of their radii, they can be coupled together. But for nanorods, the spacing is 110 nm, which is about 4 times the radius. Therefore we can neglect the coupling between nanorod elements. The unit cell of the equivalent circuit model is represented in FIG. 5(b). Due to periodicity, we can convert it to a compact resonant circuit as depicted in FIG. 5(c). The effects of all the capacitances are included in Cₛₜ and Cᵣₜ for total capacitances arising from the spheres and rods, respectively.

Obtaining the equivalent values of the circuit elements, by way of non-limiting example only, we find:

Lₛ=10.1 femtoH (inductance of sphere)

C_{fs}=2.78 attoF (fringe capacitance of sphere)

Cᵣ=293.6 femto (capacitance of rod)

C_{fr}=6.67 attoF (fringe capacitance of rod)

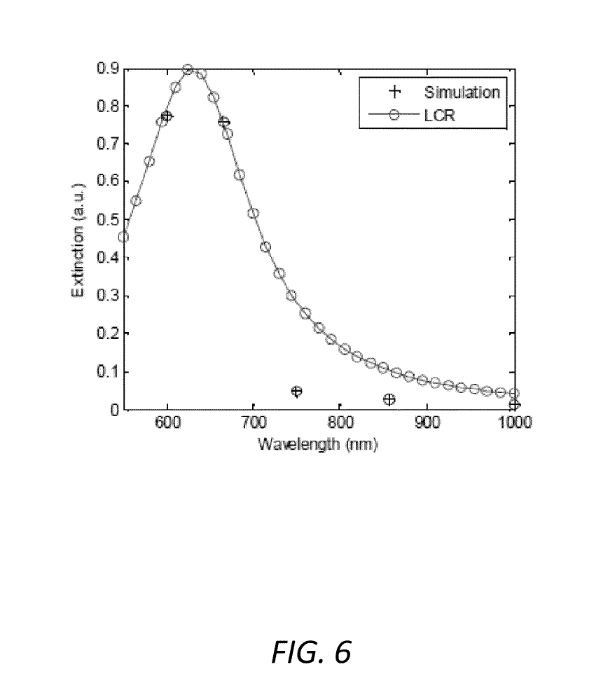

and the total values for the inductor-capacitor-resistor (LCR) circuit are L˜10.1 femtoH, C˜11.1 attoF, R˜233.4Ω. This is a band-pass filter with a Q factor of 7.78 and a fractional bandwidth of 0.1288, centered at the frequency corresponding to light of 630 nm. Thus, the bandwidth of the resonance is about 81 nm, which matches the spectral properties of FIG. 1. A plot of such a response is shown in FIG. 6, along with the simulation data of FIG. 1.

Thus, we have studied the spectral properties of a composite plasmonic structure made from Au (or Ag or Al) nanospheres and ZnTe (or Si or Ge) nanorods or nanowires. For applications in solar harvesting, we investigated the effects of structural parameters on light absorption and scattering. We found an optimum design for nanorod length and array spacing which can provide multifold conversion efficiency. In other words, a small set of nanorods of different diameters can span the solar spectrum. Moreover, we used an LCR equivalent circuit model to intuitively study the response of our proposed structure. One of the main conclusions of our work is the role of plasmonic Au spheres incorporated into our design. We found that the Au can have two major benefits: one is to help in fabrication for the growth of the ZnTe nanorods, and another is to provide more absorption in the ZnTe nanorods through LSPR. The results of these studies are of significant importance toward novel devices for solar harvesting and the like.

In summary, FIG. 7 is a schematic diagram illustrating exemplary embodiments of the composite plasmonic nanostructure 10 of the present disclosure, highlighting their geometrical shapes and the inclusion of a rod-like semiconductor structure 14 and a plasmonic or non-plasmonic nano-antenna 12 adjacent to it.

Although the present disclosure is illustrated and described herein with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following claims.

What is claimed is:

1. A composite plasmonic nanostructure for the enhanced extinction of electromagnetic waves, comprising:
an elongate nanostructure; and
a nanoparticle disposed adjacent to the elongate nanostructure.

2. The nanostructure of claim 1, wherein:
the elongate nanostructure comprises one or more of zinc telluride (ZnTe), silicon (Si), germanium (Ge), and another semiconductor material; and
the nanoparticle comprises one or more of gold (Au), silver (Ag), aluminum (Al), a plasmonic nanoparticle, and a non-plasmonic nanoparticle.

3. The nanostructure of claim 1, wherein the nanoparticle is disposed adjacent to a free end of the elongate nanostructure.

4. The nanostructure of claim 1, further comprising one of a shell disposed about and a radial junction formed within the elongate nanostructure.

5. The nanostructure of claim 1, wherein the elongate nanostructure has a length of between 200 nm and 10,000 nm and a diameter of between 10 nm and 2,000 nm.

6. The nanostructure of claim 1, wherein the nanoparticle has a diameter of between 10 nm and 2,000 nm.

7. The nanostructure of claim 1, wherein the nanoparticle and the elongate nanostructure collectively provide the extinction of light having a wavelength of between 200 nm and 2,000 nm.

8. The nanostructure of claim 1, further comprising a plurality of additional elongate nanostructures and additional nanoparticles disposed adjacent to the elongate nanostructure and nanopartical in an array.

9. The nanostructure of claim 8, further comprising the plurality of additional elongate nanostructures and additional nanoparticles disposed adjacent to the elongate nanostructure and nanopartical in a vertical array.

10. The nanostructure of claim 1, wherein the elongate nanostructure is grown using a vapor-liquid-solid (VLS) technique and the nanoparticle as a catalyst.

11. The nanostructure of claim 1, wherein the elongate nanostructure and the nanoparticle are used as or disposed within a photovoltaic device.

12. A method for providing a composite plasmonic nanostructure for the enhanced extinction of electromagnetic waves, comprising:
providing an elongate nanostructure; and
providing a nanoparticle disposed adjacent to the elongate nanostructure.

13. The method of claim 12, wherein:
the elongate nanostructure comprises one or more of zinc telluride (ZnTe), silicon (Si), germanium (Ge), and another semiconductor material; and
the nanoparticle comprises one or more of gold (Au), silver (Ag), aluminum (Al), a plasmonic nanoparticle, and a non-plasmonic nanoparticle.

14. The method of claim 12, wherein the nanoparticle is disposed adjacent to a free end of the elongate nanostructure.

15. The method of claim 12, further comprising providing one of a shell disposed about and a radial junction formed within the elongate nanostructure.

16. The method of claim 12, wherein the elongate nanostructure has a length of between 200 nm and 10,000 nm and a diameter of between 10 nm and 2,000 nm.

17. The method of claim 12, wherein the nanoparticle has a diameter of between 10 nm and 2,000 nm.

18. The method of claim 12, wherein the nanoparticle and the elongate nanostructure collectively provide the extinction of light having a wavelength of between 200 nm and 2,000 nm.

19. The method of claim 12, further comprising providing a plurality of additional elongate nanostructures and additional nanoparticles disposed adjacent to the elongate nanostructure and nanopartical in an array.

20. The method of claim 19, further comprising providing the plurality of additional elongate nanostructures and additional nanoparticles disposed adjacent to the elongate nanostructure and nanopartical in a vertical array.

21. The method of claim 12, wherein the elongate nanostructure is grown using a vapor-liquid-solid (VLS) technique and the nanoparticle as a catalyst.

22. The method of claim 12, wherein the elongate nanostructure and the nanoparticle are used as or disposed within a photovoltaic device.
